(19) United States
(12) Patent Application Publication
(10) Pub. No.: US 2026/0016928 A1
(43) Pub. Date: Jan. 15, 2026

(54) Increasing Visibility of Similar Designators

(71) Applicant: International Business Machines Corporation, Armonk, NY (US)

(72) Inventors: Grzegorz Piotr Szczepanik, Krakow (PL); Sakthivel Ruthrasekar, Dublin (IE); Sujeily Fonseca-Gonzalez, Raleigh, NC (US)

(21) Appl. No.: 18/768,474

(22) Filed: Jul. 10, 2024

(51) Int. Cl. G06F 3/0482

(52) U.S. Cl. CPC G06F 3/0482

(57) ABSTRACT

A computer implemented method modifies designators. A processor set identifies a plurality of designators that have a set of similarity metrics that are within a similarity threshold. The processor set modifies the plurality of designators to form a plurality of modified designators in which the set of similarity metrics for the plurality of modified designators is no longer within the similarity threshold.

### BACKGROUND

The disclosure relates generally to an improved computer system and more specifically to increasing the differentiation between visibly similar designators in a computer system.

A user can view, analyze, and perform actions based on the display of information on a graphical user interface. For example, server computers can be displayed on a graphical user interface using graphical elements such as labels and graphical icons. With this example, the user may reboot a selected sever computer by identifying the label and graphical icon displayed on the graphical user interface for that server computer. The label is a designator in this example and is used to distinguish the server from other servers. The user selects the server computer using the designator and initiates the reboot of the server computer from the selection.

In another example, a file can be sent to another user based on the identification designator and graphical icon representing the file. In yet another example, files can be deleted based on identifying those files from designator and graphical icons representing the files. These and other actions are performed by a user viewing the designator and graphical icons on the graphical user interface.

### SUMMARY

According to one illustrative embodiment, a computer implemented method modifies designators. A processor set identifies a plurality of designators that have a set of similarity metrics that are within a similarity threshold. The processor set modifies the plurality of designators to form a plurality of modified designators in which the set of similarity metrics for the plurality of modified designators is no longer within the similarity threshold. According to other illustrative embodiments, a computer system and a computer program product for modifying be designators are provided.

### BRIEF DESCRIPTION OF THE DRAWINGS

FIG. 1 is a block diagram of a computing environment in which illustrative embodiments can be implemented;

FIG. 2 is a pictorial representation of a network of data processing systems in which illustrative embodiments can be implemented;

FIG. 3 is an illustration of designators in accordance with an illustrative embodiment;

FIG. 4 is an illustration of modified designators in accordance with an illustrative embodiment;

FIG. 5 is a flowchart of a process for modifying designators in accordance with an illustrative embodiment;

FIG. 6 is a flowchart of a process for modifying designators in accordance with an illustrative embodiment;

FIG. 7 is a flowchart of a process for modifying a plurality of designators in accordance with an illustrative embodiment;

FIG. 8 is a flowchart of a process for modifying a plurality of designators in accordance with an illustrative embodiment;

FIG. 9 is a flowchart of a process for modifying a plurality of designators in accordance with an illustrative embodiment;

FIG. 10 is a flowchart of a process for presenting modified designators in importance with an illustrative embodiment;

FIG. 11 is a flowchart of a process for presenting modified designators in importance with an illustrative embodiment; and

FIG. 12 is a block diagram of a data processing system in accordance with an illustrative embodiment.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment ("CPP embodiment" or “CPP”) is a term used in the present disclosure to describe any set of one, or more, storage media (also called "mediums") collectively included in a set of one, or more, storage devices that collectively include machine readable code corresponding to instructions and/or data for performing computer operations specified in a given CPP claim. A "storage device" is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits / lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

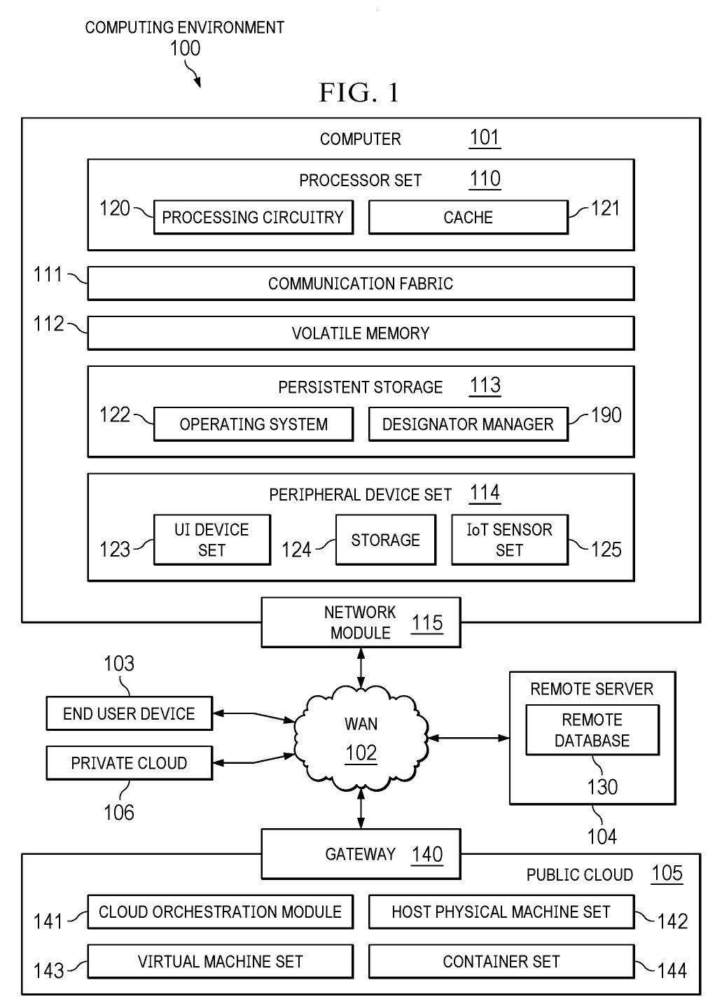

With reference now to the figures in particular with reference to FIG. 1, a block diagram of a computing environment is depicted in accordance with an illustrative embodiment. Computing environment 100 contains an example of an environment for the execution of at least some of the computer code involved in performing the inventive methods, such as designator manager 190. In addition to designator manager 190, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and designator manager 190, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in designator manager 190 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input / output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in designator manager 190 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES: Public cloud 105 and private cloud 106 are programmed and configured to deliver cloud computing services and/or microservices (not separately shown in FIG. 1). Unless otherwise indicated, the word “microservices” shall be interpreted as inclusive of larger “services” regardless of size. Cloud services are infrastructure, platforms, or software that are typically hosted by third-party providers and made available to users through the internet. Cloud services facilitate the flow of user data from front-end clients (for example, user-side servers, tablets, desktops, and laptops), through the internet, to the provider’s systems, and back. In some embodiments, cloud services may be configured and orchestrated according to an “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The illustrative embodiments recognize and take into account one or more different considerations as described herein. A problem is present with human users distinguishing between similar strings. For example, an issue can be present with similarly sounding hostnames of servers. This issue can be exaggerated by cases when characters are easy to be mistaken. For example, a mistake can be made between the “o” letter and the number “zero.” As another example, a confusion can occur between capital “I” and a lower case “l.” Also, human users can be terrible with spotting differences and recalling similar numbers such as 1234 versus 1243.

In another example, a user intends to reboot a server with the designator “AS4MD5.” This server can be easily mistaken for “AS4MB5” when selecting a server. In these examples, a user is a human user. This mistake in selecting a server can result in restarting the incorrect server computer. Restarting the incorrect server computer can have undesired consequences.

Thus, illustrative examples provide a computer implemented method, apparatus, system, and computer program product for reducing issues with similarity between designators. In one illustrative example, pairs of similar designators are identified. These designators can be similar in the written form, the spoken form, or both written form and the spoken form. With the identification of a pair of similar designators, these designators can be modified or replaced with designators that increase the ability to distinguish between the pair of similar designators.

In one example, the designator can be a name and an expanded designator can be modified based on the part of the name that differentiates between the names of the designators. For example, “AS4M05” and “AS4MO5” are a pair of designators for server computers. This pair of designators is identified and modified. In this example, “AS4MO5” is modified to be “AS4MOrange5”, and “AS4M05” is modified to be “AS4MZero5.” As a result, this type of modification of designators can make identifying the correct server computer less error prone.

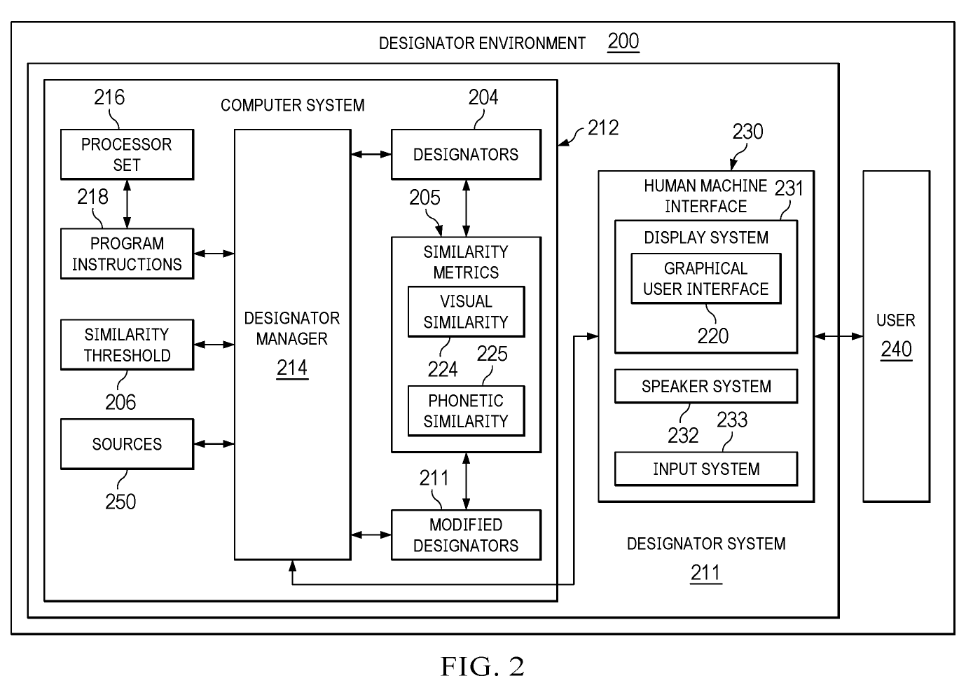

With reference now to FIG. 2, a block diagram of a designator environment is depicted in accordance with an illustrative embodiment. In this illustrative example, designator environment 200 includes components that can be implemented in hardware such as the hardware shown in computing environment 100 in FIG. 1.

In this example, designator system 202 can operate to increase the visibility of different designators that reduces mistaking one designator for another designator. In other words, designator system 202 can increase the ability to discern the difference between designators. Increasing the visibility to distinguish one designator from another designator results in less error occurring from the similarity of the names that are sufficiently similar to each other to cause mistakes in performing actions based on the designators.

Designator system 202 is comprised of a number of different components. In this example, designator system 202 includes computer system 212 and designator manager 214. As depicted, designator manager 214 is located in computer system 212.

Designator manager 214 may be implemented using designator manager 190 in FIG. 1.

Designator manager 214 can be implemented in software, hardware, firmware or a combination thereof. When software is used, the operations performed by designator manager 214 can be implemented in program instructions configured to run on hardware, such as a processor unit. When firmware is used, the operations performed by designator manager 214 can be implemented in program instructions and data and stored in persistent memory to run on a processor unit. When hardware is employed, the hardware can include circuits that operate to perform the operations in designator manager 214.

In the illustrative examples, the hardware can take a form selected from at least one of a circuit system, an integrated circuit, an application-specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field-programmable logic array, a field-programmable gate array, and other suitable hardware devices. Additionally, the processes can be implemented in organic components integrated with inorganic components and can be comprised entirely of organic components excluding a human being. For example, the processes can be implemented as circuits in organic semiconductors.

As used herein, “a number of” when used with reference to items, means one or more items. For example, “a number of operations” is one or more operations.

Further, the phrase “at least one of,” when used with a list of items, means different combinations of one or more of the listed items can be used, and only one of each item in the list may be needed. In other words, “at least one of” means any combination of items and a number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combination of these items can be present. In some illustrative examples, “at least one of” can be, for example, without limitation, two of item A; one of item B; and ten of item C; four of item B and seven of item C; or other suitable combinations.

Computer system 212 is a physical hardware system and includes one or more data processing systems. When more than one data processing system is present in computer system 212, those data processing systems are in communication with each other using a communications medium. The communications medium can be a network. The data processing systems can be selected from at least one of a computer, a server computer, a tablet computer, or some other suitable data processing system.

As depicted, computer system 212 includes processor set 216 that is capable of executing program instructions 218 implementing processes in the illustrative examples. In other words, program instructions 218 are computer-readable program instructions. Processor set 216 is an example of processor set 110 in FIG. 1.

As used herein, a processor unit in processor set 216 is a hardware device and is comprised of hardware circuits such as those on an integrated circuit that respond to and process instructions and program code that operate a computer. Processor set 216 can be a number of processor units that can be implemented using processor set 110 in FIG. 1. The processor units can also be referred to as computer processors. When processor set 216 executes program instructions 218 for a process, processor set 216 can be one or more processor units that are in the same computer or in different computers. In other words, the process can be distributed between processor units in processor set 216 on the same or different computers in computer system 212.

Further, processor set 216 can include the same type or different types of processor units. For example, processor set 216 can be selected from at least one of a single core processor, a dual-core processor, a multi-processor core, a general-purpose central processing unit (CPU), a graphics processing unit (GPU), a digital signal processor (DSP), or some other type of processor unit.

Although not shown, processor set 216 can also include other components in addition to the processor units or processing circuitry. For example, processor set 216 can also include a cache or other components used with processor units or other processing circuitry.

In one illustrative example, designator manager 214 operates to selectively modify designators 204. For example, designator manager 214 identifies a plurality of designators 204 that have a set of similarity metrics 205 that are within similarity threshold 206.

As used herein, a “set of” when used with reference to items means one or more items. For example, a set of similarity metrics 205 is one or more of similarity metrics 205. In this example, the plurality of designators 204 is two or more of designators 204.

The set of similarity metrics 205 can include one or more different types of metrics. For example, the set of similarity metrics 205 can represent visual similarity 224 between the plurality of designators. For example, a designator can be comprised of symbols such as letters, numbers, and other graphical symbols. The visual similarity between one or more of the symbols can be measured using a similarity metric based on visual similarity 224.

In another example, the set of similarity metrics 205 represent phonetic similarity 225 between the plurality of designators. In this example, the manner in which different designators are pronounced can have similarities that are measured based on phonetic similarity 225.

Examples of the set of similarity metrics 205 can include at least one of a string similarity metric, a phonetic similarity metric, a Levenshtein distance, a Hamming distance, a Jaro-Winkler distance, a cosine similarity, a Jaccard similarity, or some other type of metric that can be used to measure the similarity between designators 204. These similarity metrics can provide values indicating a distance between designators 204. For example, a greater value can indicate a greater distance between designators 204, indicating less similarity. A smaller value indicates a smaller distance between designators 204, indicating more similarity.

Further in this example, a designator is an identifier used to uniquely identify an item within a dataset. For example, the dataset can be server computers. In another example, the dataset can be files, logs, routers, switches, components, or other types of items. The designator makes it easier for a user to at least one of identify, locate, organize, reference, or interpret the data or perform actions on items in the dataset.

In this illustrative example, a similarity metric can be considered to be within similarity threshold 206 when the two designators are sufficiently close to each other that the designators can be confused or mistaken for each other. In this example, the similarity threshold 206 is a minimum value of similarity between designators. In another illustrative example, the similarity threshold 206 can be a maximum value that indicates the similarity between the designators. In another illustrative example, similarity threshold 206 can be a range of values. With this example, when the similarity metric for two designators is within the range of values for similarity threshold 206, the two designators are considered to be sufficiently similar to cause confusion or be mistaken for each other.

In this illustrative example, similarity threshold 206 can be identified in a number of different ways. For example, user feedback can be used to identify a similarity threshold. With this technique, end-users can be provided with multiple sets of designators that are associated with similarity metrics. Each of these sets of designators can have different similarity metrics. The end-users can then select sets of designators that they find difficult to distinguish. Similarity threshold 206 can be set based on these selections from the end-users. As another example, an ASTS algorithm can be used to select similarity threshold 206.

In this illustrative example, designator manager 214 modifies the plurality of designators 204 to form a plurality of modified designators 211. In this example, the set of similarity metrics 205 for the plurality of modified designators 211 is no longer within similarity threshold 206. In other words, the modification to the plurality of designators 204 is such that a user is less likely to confuse or mistakenly select an incorrect designator by confusing that designator with a different designator.

In one illustrative example, the modification of the plurality of designators 204 can be performed using a group of one or more sources 250. The group of sources can take a number of different forms. For example, the group of sources can be a library, a database, a machine learning model, or other collection of information that can be used to modify the plurality designators 204 to form the plurality of modified designators 211.

For example, a source can be a database of distinct names, a database of distinct words, or some other collection of terms that can be used to modify the plurality of designators 204 such that designators within this plurality of designators are more distinct and easier to distinguish. In other words, the visibility of individual designators is increased such that they can be distinguished from other designators in the plurality of designators 204 to form the plurality of modified designators 211.

In one illustrative example, the plurality designators 204 can be a first designator and a second designator. In modifying the plurality of designators, designator manager 214 modifies the first designator and the second designator to form the plurality of modified designators 211.

In another example, modifying the plurality of designators 204 comprises designator manager 214 modifying the designator in the two designators to form the plurality of modified designators 211. In other words, a single designator is modified instead of modifying both designators in this example. When more than two designators are present, the number of designators 204 modified are a subset of all designators 204 can be modified such that the set of similarity metrics 205 for the plurality of modified designators 211 is no longer within the similarity threshold 206.

Further, in modifying the plurality designators 204, designator manager 214 can modify at least one of a symbol or a color in the plurality of designators 204 to form the plurality of modified designators 211 in which the set of similarity metrics 205 for the plurality of modified designators 211 is no longer within similarity threshold 206.

In the illustrative example, designator manager 214 can present the plurality of modified designators 211 in a number of different ways in human machine interface 230. As depicted, human machine interface (HMI) 230 comprises display system 231, speaker system 232, and input system 233.

Display system 231 is a physical hardware system and includes one or more display devices on which graphical user interface 220 can be displayed. The display devices can include at least one of a light emitting diode (LED) display, an organic light emitting diode (OLED) display, a computer monitor, a projector, a flat panel display, a heads-up display (HUD), a head-mounted display (HMD), smart glasses, augmented reality glasses, or some other suitable device that can output information for the visual presentation of information.

In this example, speaker system 232 is a physical hardware system that includes one or more speakers that can generate sound. User 240 is a person that can interact with graphical user interface 220 through user input generated by input system 233 for computer system 212. Input system 233 is a physical hardware system and can be selected from at least one of a mouse, a keyboard, a touch pad, a trackball, a touchscreen, a stylus, a motion sensing input device, a gesture detection device, a data glove, a cyber glove, a haptic feedback device, or some other suitable type of input device.

In one example, designator manager 214 displays the plurality of modified designators 211 in graphical user interface 220 on display system 231. In another illustrative example, designator manager 214 audibly presents the plurality of modified designators 211 using speaker system 232.

In one illustrative example, one or more solutions are present that overcome a problem with similar designators that can cause confusion in selecting or analyzing information. As a result, one or more technical solutions provide an ability to increase the differentiation between similar designators. In these illustrative examples, designators are analyzed to identify designators that are within a similarity threshold. The similarity threshold is set as a standard for when a plurality of designators are considered to be sufficiently similar for further processing in the different examples. As depicted, the designators that are determined to be within the similarity threshold are modified. These modifications are performed on one or more of the designators in the plurality of designators such that the plurality of designators are no longer within the similarity threshold. For example, this plurality of modified designators may no longer be considered to be similar enough to cause confusion or may be less likely to cause confusion for a user when viewing or listening to the modified designators.

The plurality of modified designators can then be displayed, audibly presented, or both be displayed and audibly presented to a user. The modified designators are easier to distinguish resulting in less errors by a user in performing actions using the modified designators.

Thus, designator manager 214 can operate to recognize potentially problematic designators such as names, use external sources to find unique terms for reference, and then create modified versions of the names to enhance error-free communication. Designator manager 214 can be a valuable tool in situations where precision in spoken or written communication is crucial.

Computer system 212 can be configured to perform at least one of the steps, operations, or actions described in the different illustrative examples using software, hardware, firmware or a combination thereof. In the illustrative example, the use of designator manager 214 in computer system 212 integrates processes for identifying and modifying designators into a practical application for reducing confusion or errors by users that perform actions on a dataset in which the designators are present. In other words, designator manager 214 in computer system 212 is directed to a practical application of processes integrated into designator manager 214 in computer system 212 that identifies designators that have similarity metrics within a similarity threshold and modify those designators such that the modified designators are no longer within the similarity threshold. These modified designators can then be at least one of displayed or audibly presented to a user in which the user uses the modified designator for various actions. These actions can include, for example, restarting a server, sending a file to a recipient, deleting a log, or other actions.

The illustration of designator environment 200 in FIG. 2 is not meant to imply physical or architectural limitations to the manner in which an illustrative embodiment can be implemented. Other components in addition to or in place of the ones illustrated may be used. Some components may be unnecessary. Also, the blocks are presented to illustrate some functional components. One or more of these blocks may be combined, divided, or combined and divided into different blocks when implemented in an illustrative embodiment.

Although not shown, designators 204 can be located in or associated with a dataset. This dataset can be, for example, files, logs, routers, computers, switches, components, or other types of items. In these examples, user 240 can perform actions with respect to items in the dataset based on using modified designators 211 as presented to user 240 by human machine interface 230.

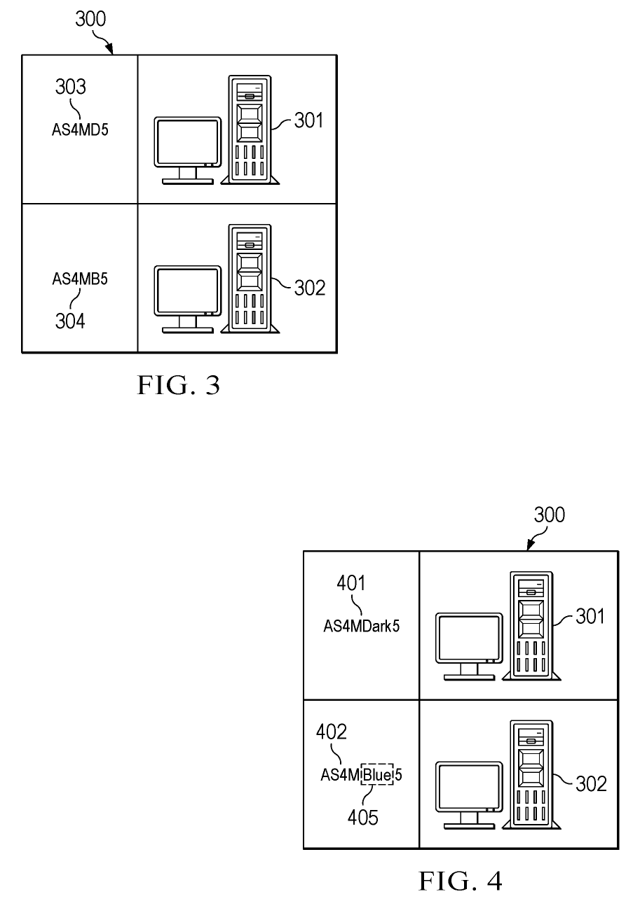

Turning next to FIG. 3, an illustration of designators is depicted in accordance with an illustrative embodiment. In this illustrative example, display 300 is an example of a display that can be displayed on a graphical user interface 220 in human machine interface 230 in FIG. 2. In this example, display 300 depicts servers such as server 301 and server 302. In this example, the servers are identified using designators. Designator 303 identifies server 301 and designator 304 identifies server 302. Designator 303 is “AS4MD5” while designator 304 is “AS4MB5” in this example.

A user can perform actions on these servers. Actions can be performed on a particular server by selecting that server in display 300. As depicted, these designators have similarity metrics that are within a similarity threshold. In other words, an analysis of the similarity between these two designators indicates that they are sufficiently similar that a user can have difficulties distinguishing between the two servers. Performing an action on the incorrect server can result in undesired consequences.

With reference next to FIG. 4, an illustration of modified designators is depicted in accordance with an illustrative embodiment. In this illustrative example, designator 303 and designator 304 and display 300 from FIG. 3 have been modified to form modified designator 401 and modified designator 402 in display 300.

In this example, the plurality of designators is modified based on a differing part between the different designators. The differing part is the part of the designator that is different between the other designator. For example, the differing part that is different between two designators can be one or more symbols such as a letter, a number, or other symbol.

In this example, differing parts between the two designators is “D” for designator 303 and “B” for designator 304. In this example, expansion of “D” is “Dark” and the expansion of “B” is Blue. As a result, modified designator 401 is “AS4MDark” and modified designator 402 is “AS4MBlue5”. These modified designators have a higher visibility with respect to the user being able to distinguish between the two designators as compared to the unmodified designators in FIG. 3. To further distinguish these designators, a change in color can be made as part of the modification of a designator. For example, the characters “Blue” in designator 402 can have color 405 that is different from the color used for the other portions of modified designator 402. For example, color 405 can be blue while the other portion of modified designator 402 has a color that is black. In these examples, the color can be for at least one of the symbols or the background.

The illustration of modifying designators in FIG. 3 and FIG. 4 are provided as an example and not meant to limit the manner in which other illustrative examples can be implemented. For example, in other illustrative examples the designators identified as dissimilar can be three designators, four designators, or some other number of designators in addition to the two designators depicted in this example. Further, the modification can be a change in color rather than expansion of the designators for changing color and expansion of the designators in some illustrative examples. In still other illustrative examples, the modification can take other forms. For example, “Blue” in designator 402 and “Dark” in designator 401 can be displayed as flashing text. In another illustrative example, the modification can be a change in the size or type of font.

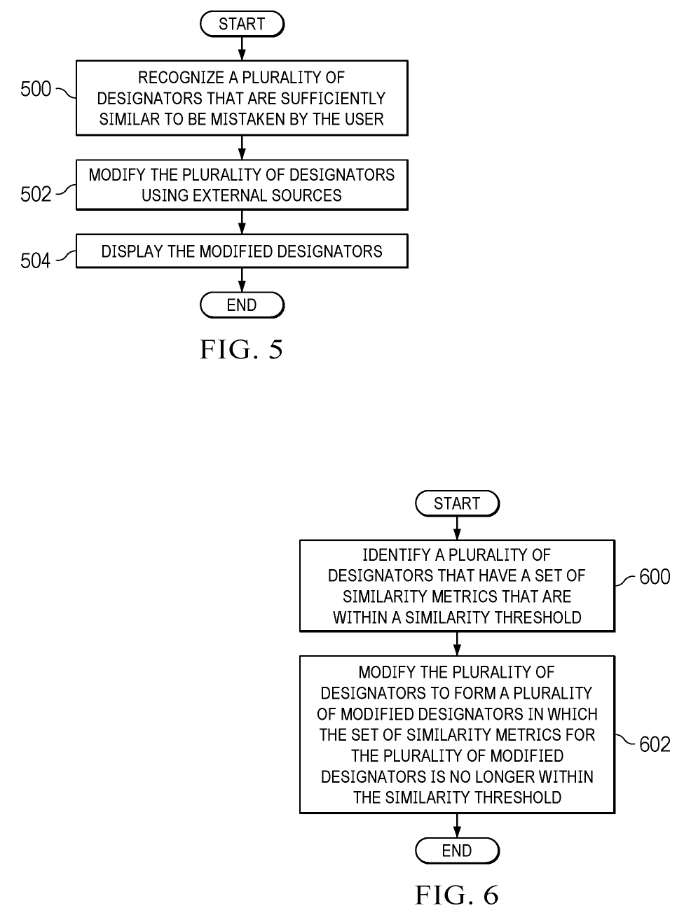

With reference now to FIG. 5, a flowchart of a process for modifying designators is depicted in accordance with an illustrative embodiment. The process in FIG. 5 can be implemented in hardware, software, or both. When implemented in software, the process can take the form of program instructions that are run by a processor set located in one or more hardware devices in one or more computer systems. For example, the process can be implemented in designator manager 214 in computer system 212 in FIG. 2.

The process begins by recognizing a plurality of designators that are sufficiently similar as to be mistaken by the user (step 500). In step 500, these designators identify names or terms that resemble each other to a such a degree where designators identified are prone to being mispronounced or confused. For example, names such as “Smith” and “Smyth” are sufficiently similar that these names can be mistakenly spoken as one another. The similarity in this example can be performed using a string similarity metric, such as a Levenshtein distance.

The process modifies the plurality of designators using external sources (step 502). In step 502, the process accesses external sources to gather a diverse range of distinct names, words, or terms for use in performing the modification of the designators. In this example, these sources can include at least one of the NATO phonetic alphabet (Alpha, Bravo, Charlie, etc.), colors (Red, Blue, Green, etc.), geographical names (such as cities or countries), or any other collections of unique words and terms. These external sources serve as a reference for generating modifications to the designators. For example, modifications to the designators can be generated using a consideration of relevant local language specifically. For example, the NATO alphabet is not suitable for non-Latin script languages. In this case a different source can be used.

The process displays the modified designators (step 504). The process terminates thereafter. In step 504, once the process recognizes similar names that are susceptible to mispronunciations and modifies these names using the distinct words and terms from external sources, these modified designators can be displayed to the user to perform different actions using these modified designators. In these examples, this display of the modified names are less prone to cause errors in performing actions.

This modification process in FIG. 5 ensures that names and terms with similarities are transformed into more distinctive and less easily confused versions, reducing the likelihood of errors in understanding and communication. This process in designator manager 214 can be implemented for display interfaces. For example, designator manager 214 can be implemented in libraries like Qt for graphical user interfaces or JavaScript for Web interfaces.

Turning next to FIG. 6, a flowchart of a process for modifying designators is depicted in accordance with an illustrative embodiment. The process in FIG. 6 can be implemented in hardware, software, or both. When implemented in software, the process can take the form of program instructions that are run by a processor set located in one or more hardware devices in one or more computer systems. For example, the process can be implemented in designator manager 214 in computer system 212 in FIG. 2.

The process identifies a plurality of designators that have a set of similarity metrics that are within a similarity threshold (step 600). The process modifies the plurality of designators to form a plurality of modified designators in which the set of similarity metrics for the plurality of modified designators is no longer within the similarity threshold (step 602). The process terminates thereafter.

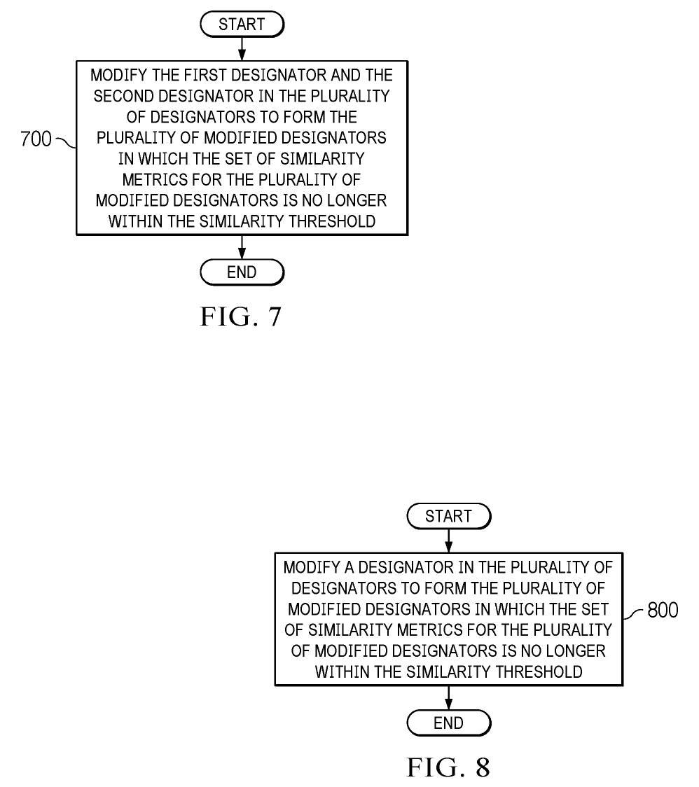

Turning now to FIG. 7, a flowchart of a process for modifying a plurality of designators is depicted in accordance with an illustrative embodiment. The process in this figure is an example of an implementation of step 602 in FIG. 6. In this example, the plurality of designators comprises a first designator and a second designator.

The process modifies the first designator and the second designator in the plurality of designators to form the plurality of modified designators in which the set of similarity metrics for the plurality of modified designators is no longer within the similarity threshold (step 700). The process terminates thereafter.

With reference to FIG. 8, a flowchart of a process for modifying a plurality of designators is depicted in accordance with an illustrative embodiment. The process in this figure is an example of an implementation of step 602 in FIG. 6. In this depicted example, the plurality of designators comprises two designators.

The process modifies a designator in the plurality of designators to form the plurality of modified designators in which the set of similarity metrics for the plurality of modified designators is no longer within the similarity threshold (step 800). The process terminates thereafter.

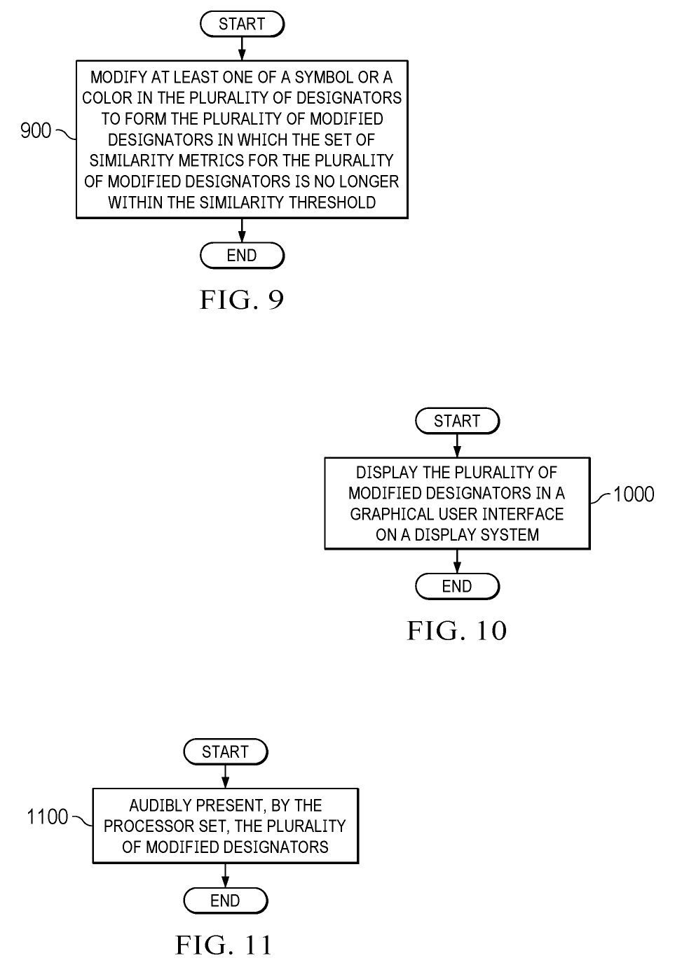

Next in FIG. 9, a flowchart of a process for modifying a plurality of designators is depicted in accordance with an illustrative embodiment. The process in this figure is an example of an implementation of step 602 in FIG. 6.

The process modifies at least one of a symbol or a color in the plurality of designators to form the plurality of modified designators in which the set of similarity metrics for the plurality of modified designators is no longer within the similarity threshold (step 900). The process terminates thereafter.

Turning now to FIG. 10, a flowchart of a process for presenting modified designators is depicted in accordance with an illustrative embodiment. The process in this flowchart is an example of an additional step that can be performed with the steps in FIG. 6.

The process displays the plurality of modified designators in a graphical user interface on a display system (step 1000). The process terminates thereafter.

With reference next to FIG. 11, a flowchart of a process for presenting modified designators is depicted in accordance with an illustrative embodiment. The process in this flowchart is an example of an additional step that can be performed with the steps in FIG. 6.

The process audibly presents, by the processor set, the plurality of modified designators (step 1100). The process terminates thereafter.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks can be implemented as program instructions, hardware, or a combination of the program instructions and hardware. When implemented in hardware, the hardware may, for example, take the form of integrated circuits that are manufactured or configured to perform one or more operations in the flowcharts or block diagrams. When implemented as a combination of program instructions and hardware, the implementation may take the form of firmware. Each block in the flowcharts or the block diagrams can be implemented using special purpose hardware systems that perform the different operations or combinations of special purpose hardware and program instructions run by the special purpose hardware.

In some alternative implementations of an illustrative embodiment, the function or functions noted in the blocks may occur out of the order noted in the figures. For example, in some cases, two blocks shown in succession can be performed substantially concurrently, or the blocks may sometimes be performed in the reverse order, depending upon the functionality involved. Also, other blocks can be added in addition to the illustrated blocks in a flowchart or block diagram.

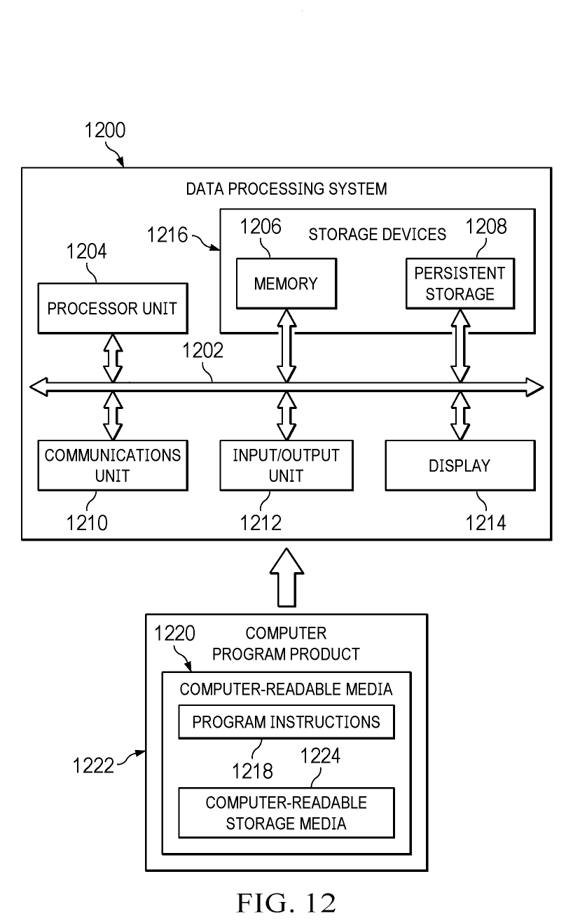

Turning now to FIG. 12, a block diagram of a data processing system is depicted in accordance with an illustrative embodiment. Data processing system 1200 can be used to implement computers and computing devices in computing environment 100 in FIG. 1. Data processing system 1200 can also be used to implement computer system 212 in FIG. 2. In this illustrative example, data processing system 1200 includes communications framework 1202, which provides communications between processor unit 1204, memory 1206, persistent storage 1208, communications unit 1210, input/output (I/O) unit 1212, and display 1214. In this example, communications framework 1202 takes the form of a bus system.

Processor unit 1204 serves to execute instructions for software that can be loaded into memory 1206. Processor unit 1204 includes one or more processors. For example, processor unit 1204 can be selected from at least one of a multicore processor, a central processing unit (CPU), a graphics processing unit (GPU), a physics processing unit (PPU), a digital signal processor (DSP), a network processor, or some other suitable type of processor. Further, processor unit 1204 can be implemented using one or more heterogeneous processor systems in which a main processor is present with secondary processors on a single chip. As another illustrative example, processor unit 1204 can be a symmetric multi-processor system containing multiple processors of the same type on a single chip.

Memory 1206 and persistent storage 1208 are examples of storage devices 1216. A storage device is any piece of hardware that is capable of storing information, such as, for example, without limitation, at least one of data, program instructions in functional form, or other suitable information either on a temporary basis, a permanent basis, or both on a temporary basis and a permanent basis. Storage devices 1216 may also be referred to as computer-readable storage devices in these illustrative examples. Memory 1206, in these examples, can be, for example, a random-access memory or any other suitable volatile or non-volatile storage device. Persistent storage 1208 may take various forms, depending on the particular implementation.

For example, persistent storage 1208 may contain one or more components or devices. For example, persistent storage 1208 can be a hard drive, a solid-state drive (SSD), a flash memory, a rewritable optical disk, a rewritable magnetic tape, or some combination of the above. The media used by persistent storage 1208 also can be removable. For example, a removable hard drive can be used for persistent storage 1208.

Communications unit 1210, in these illustrative examples, provides for communications with other data processing systems or devices. In these illustrative examples, communications unit 1210 is a network interface card.

Input/output unit 1212 allows for input and output of data with other devices that can be connected to data processing system 1200. For example, input/output unit 1212 may provide a connection for user input through at least one of a keyboard, a mouse, or some other suitable input device. Further, input/output unit 1212 may send output to a printer. Display 1214 provides a mechanism to display information to a user.

Instructions for at least one of the operating system, applications, or programs can be located in storage devices 1216, which are in communication with processor unit 1204 through communications framework 1202. The processes of the different embodiments can be performed by processor unit 1204 using computer-implemented instructions, which may be located in a memory, such as memory 1206.

These instructions are referred to as program instructions, computer usable program instructions, or computer-readable program instructions that can be read and executed by a processor in processor unit 1204. The program instructions in the different embodiments can be embodied on different physical or computer-readable storage media, such as memory 1206 or persistent storage 1208.

Program instructions 1218 are located in a functional form on computer-readable media 1220 that is selectively removable and can be loaded onto or transferred to data processing system 1200 for execution by processor unit 1204. Program instructions 1218 and computer-readable media 1220 form computer program product 1222 in these illustrative examples. In the illustrative example, computer-readable media 1220 is computer-readable storage media 1224.

Computer-readable storage media 1224 is a physical or tangible storage device used to store program instructions 1218 rather than a medium that propagates or transmits program instructions 1218. Computer-readable storage media 1224, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Alternatively, program instructions 1218 can be transferred to data processing system 1200 using a computer-readable signal media. The computer-readable signal media are signals and can be, for example, a propagated data signal containing program instructions 1218. For example, the computer-readable signal media can be at least one of an electromagnetic signal, an optical signal, or any other suitable type of signal. These signals can be transmitted over connections, such as wireless connections, optical fiber cable, coaxial cable, a wire, or any other suitable type of connection.

Further, as used herein, “computer-readable media 1220” can be singular or plural. For example, program instructions 1218 can be located in computer-readable media 1220 in the form of a single storage device or system. In another example, program instructions 1218 can be located in computer-readable media 1220 that is distributed in multiple data processing systems. In other words, some instructions in program instructions 1218 can be located in one data processing system while other instructions in program instructions 1218 can be located in one data processing system. For example, a portion of program instructions 1218 can be located in computer-readable media 1220 in a server computer while another portion of program instructions 1218 can be located in computer-readable media 1220 located in a set of client computers.

The different components illustrated for data processing system 1200 are not meant to provide architectural limitations to the manner in which different embodiments can be implemented. In some illustrative examples, one or more of the components may be incorporated in or otherwise form a portion of, another component. For example, memory 1206, or portions thereof, may be incorporated in processor unit 1204 in some illustrative examples. In other examples, more than one processor unit can be present. The different illustrative embodiments can be implemented in a data processing system including components in addition to or in place of those illustrated for data processing system 1200. Other components shown in FIG. 12 can be varied from the illustrative examples shown. The different embodiments can be implemented using any hardware device or system capable of running program instructions 1218.

Thus, illustrative embodiments of the present invention provide a computer implemented method, computer system, and computer program product for modifying designators. In one illustrative example, a computer implemented method modifies designators. A processor set identifies a plurality of designators that have a set of similarity metrics that are within a similarity threshold. The processor set modifies the plurality of designators to form a plurality of modified designators in which the set of similarity metrics for the plurality of modified designators is no longer within the similarity threshold.

The illustrative examples provide an ability to display information in a manner that increases the ability for a user to more easily select and analyze information. In the illustrative examples, a plurality of designators that are identified as being similar enough to cause confusion or selection of incorrect information are modified to form a plurality of modified designators that are easier to distinguish from each other as compared to the plurality of designators without modifications. These designators can then be presented on a display system or audibly through a speaker system to a user such that the user can more easily distinguish between different designators. Thus, illustrative examples provide a practical application for modifying designators.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

The descriptions of the various embodiments of the present invention have been presented for purposes of illustration but are not intended to be exhaustive or limited to the embodiments disclosed. Not all embodiments will include all of the features described in the illustrative examples. Further, different illustrative embodiments may provide different features as compared to other illustrative embodiments. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. A computer implemented method for modifying designators, the computer implemented method comprising:
identifying, by a processor set, a plurality of designators that have a set of similarity metrics that are within a similarity threshold; and
modifying, by the processor set, the plurality of designators to form a plurality of modified designators in which the set of similarity metrics for the plurality of modified designators is no longer within the similarity threshold.

2. The computer implemented method of claim 1, wherein the plurality of designators comprises a first designator and a second designator and wherein modifying, by the processor set, the plurality of designators comprises:
modifying, by the processor set, the first designator and the second designator in the plurality of designators to form the plurality of modified designators in which the set of similarity metrics for the plurality of modified designators is no longer within the similarity threshold.

3. The computer implemented method of claim 1, wherein the plurality of designators comprises two designators and wherein modifying, by the processor set, the plurality of designators comprises:
modifying, by the processor set, a designator in the plurality of designators to form the plurality of modified designators in which the set of similarity metrics for the plurality of modified designators is no longer within the similarity threshold.

4. The computer implemented method of claim 1, wherein modifying, by the processor set, the plurality of designators comprises:
modifying, by the processor set, at least one of a symbol or a color in the plurality of designators to form the plurality of modified designators in which the set of similarity metrics for the plurality of modified designators is no longer within the similarity threshold.

5. The computer implemented method of claim 1, wherein the plurality of designators is modified based on a differing part between the plurality of designators.

6. The computer implemented method of claim 1, further comprising:
displaying, by the processor set, the plurality of modified designators in a graphical user interface on a display system.

7. The computer implemented method of claim 1, further comprising:
audibly presenting, by the processor set, the plurality of modified designators.

8. The computer implemented method of claim 1, wherein the set of similarity metrics represent a visual similarity between the plurality of designators.

9. The computer implemented method of claim 1, wherein the set of similarity metrics represent a phonetic similarity between the plurality of designators.

10. The computer implemented method of claim 1, wherein the set of similarity metrics is at least one of a similarity between at least one of a string similarity metric, a phonetic similarity metric, a Levenshtein distance, a Hamming distance, a Jaro-Winkler distance, a cosine similarity, or a Jaccard similarity.

11. A computer system comprising:
a processor set;
a set of one or more computer-readable storage media; and
program instructions, collectively stored in the set of one or more storage media, for causing the processor set to perform the following computer operations:
identify a plurality of designators that have a set of similarity metrics that are within a similarity threshold; and
modify the plurality of designators to form a plurality of modified designators in which the set of similarity metrics for the plurality of modified designators is no longer within the similarity threshold.

12. The computer system of claim 11, wherein the plurality of designators comprises a first designator and a second designator and wherein in modifying the plurality of designators, wherein the program instructions, collectively stored in the set of one or more storage media, causes the processor set to perform the following computer operations:
modify the first designator and the second designator in the plurality of designators to form the plurality of modified designators in which the set of similarity metrics for the plurality of modified designators is no longer within the similarity threshold.

13. The computer system of claim 11, wherein the plurality of designators comprises two designators and wherein in modifying the plurality of designators, the program instructions, collectively stored in the set of one or more storage media, causes the processor set to perform the following computer operations:
modify a designator in the plurality of designators to form the plurality of modified designators in which the set of similarity metrics for the plurality of modified designators is no longer within the similarity threshold.

14. The computer system of claim 11, wherein in modifying the plurality of designators, the program instructions, collectively stored in the set of one or more storage media, causes the processor set to perform the following computer operations:
modify at least one of a symbol or a color in the plurality of designators to form the plurality of modified designators in which the set of similarity metrics for the plurality of modified designators is no longer within the similarity threshold.

15. The computer system of claim 11, wherein the plurality of designators is modified based on a differing part between the plurality of designators.

16. The computer system of claim 11, wherein the program instructions, collectively stored in the set of one or more storage media, further causes the processor set to perform the following computer operations:
display the plurality of modified designators.

17. The computer system of claim 11, wherein the program instructions, collectively stored in the set of one or more storage media, further causes the processor set to perform the following computer operations:
audibly present the plurality of modified designators.

18. The computer system of claim 11, wherein similarity metrics represent a visual similarity between the plurality of designators.

19. The computer system of claim 11, wherein similarity metrics represent a phonetic similarity between the plurality of designators.

20. A computer program product for modifying designators, the computer program product comprising:
a set of one or more computer-readable storage media;
program instructions, collectively stored in the set of one or more storage media, for causing a processor set to perform the following computer operations:
identify a plurality of designators that have a set of similarity metrics that are within a similarity threshold; and
modify the plurality of designators to form a plurality of modified designators in which the set of similarity metrics for the plurality of modified designators is no longer within the similarity threshold.
